(19) United States
(12) Patent Application Publication
(10) Pub. No.: US 2025/0160170 A1
(43) Pub. Date: May 15, 2025

(54) DISPLAY MODULE AND DISPLAY DEVICE

(71) Applicant: BOE TECHNOLOGY GROUP CO., LTD., Beijing (CN)

(72) Inventor: Mingche HSIEH, Beijing (CN)

(73) Assignee: BOE TECHNOLOGY GROUP CO., LTD., Beijing (CN)

(21) Appl. No.: 18/843,309

(22) PCT Filed: Oct. 8, 2023
(86) PCT No.: PCT/CN2023/123441

§ 371 Date: Sep. 3, 2024

(30) Foreign Application Priority Data
Oct. 28, 2022 (CN) 202211337594.6

(51) Int. Cl. H10K 59/80; H10K 59/131; H10K 102/10

(52) U.S. Cl. CPC H10K 59/80524; H10K 59/131; H10K 59/873; H10K 59/8793; H10K 2102/102; H10K 2102/103

(57) ABSTRACT

A display device includes a display panel, a base layer, a vibration film, and a sound wave driving structure. The display panel has a display side and a non-display side. The display panel includes first holes penetrating the display panel. The base layer is disposed on the non-display side of the display panel. The vibration film is disposed on the display side of the display panel. The sound wave driving structure includes a first electrode layer and a second electrode layer. The first electrode layer is disposed on a surface of the base layer proximate to the display panel, and the second electrode layer is disposed on the vibration film. An orthographic projection of the first electrode layer and an orthographic projection of the second electrode layer on the base layer cover at least orthographic projections of the first holes on the base layer.

### CROSS-REFERENCE TO RELATED APPLICATIONS

This application is a national phase entry under 35 USC 371 of International Patent Application No. PCT/CN2023/123441 filed on Oct. 8, 2023, which claims priority to Chinese Patent Application No. 202211337594.6, filed on Oct. 28, 2022, which are incorporated herein by reference in their entirety.

### TECHNICAL FIELD

The present disclosure relates to the field of display technologies, and in particular, to a display module and a display device.

### BACKGROUND

Organic light-emitting diode (OLED) display panels have been widely used owing to their characteristics of self-illumination, wide viewing angle, high contrast, quick response, low power consumption, ultra-lightness and ultra-thinness, etc.

### SUMMARY

In an aspect, a display module is provided. The display module includes a display panel, a base layer, a vibration film, and a sound wave driving structure. The display panel has a display side and a non-display side. The display panel includes a plurality of first holes, and the first holes penetrate the display panel. The base layer is disposed on the non-display side of the display panel. The vibration film is disposed on the display side of the display panel. The sound wave driving structure includes a first electrode layer and a second electrode layer. The first electrode layer is disposed on a surface of the base layer proximate to the display panel, and the second electrode layer is disposed on the vibration film. An orthographic projection of the first electrode layer and an orthographic projection of the second electrode layer on the base layer cover at least orthographic projections of the plurality of first holes on the base layer.

In some embodiments, a material of the second electrode layer includes a transparent conductive material, and the second electrode layer is of a continuous whole-layer structure.

In some embodiments, the material of the second electrode layer includes indium tin oxide and/or indium zinc oxide.

In some embodiments, the display panel includes a plurality of sub-pixels, and each sub-pixel includes a light-emitting region; and the orthographic projection of the second electrode layer on the base layer is non-overlapping with an orthographic projection of the light-emitting region on the base layer.

In some embodiments, the sub-pixel includes a pixel circuit and a light-emitting device; and the orthographic projection of the second electrode layer on the base layer is non-overlapping with an orthographic projection of the pixel circuit on the base layer.

In some embodiments, the second electrode layer includes a plurality of conductive blocks and a plurality of connection lines. An orthographic projection of each conductive block on the base layer overlaps an orthographic projection of a first hole of the plurality of first holes on the base layer. The plurality of connection lines are configured to electrically connect the plurality of conductive blocks.

In some embodiments, in a top view towards the base layer, each conductive block is located in a first hole of the plurality of first holes, and a boundary of the conductive block substantially coincides with a boundary of the first hole.

In some embodiments, in a top view towards the base layer, each conductive block is located in a first hole of the plurality of first holes, and at least a portion of a boundary of the conductive block has a spacing from a boundary of the first hole; or in the top view towards the base layer, a first hole of the plurality of first holes is located in a conductive block of the plurality of conductive blocks, and at least a portion of a boundary of the conductive block has a spacing from a boundary of the first hole.

In some embodiments, the second electrode layer is of a grid structure having a plurality of first openings; and in a top view towards the base layer, light-emitting regions of the plurality of sub-pixels are located in the plurality of first openings.

In some embodiments, a material of the second electrode layer includes a transparent conductive material, and/or the material of the second electrode layer includes metal or alloy.

In some embodiments, the orthographic projection of the first electrode layer on the base layer substantially overlaps the orthographic projection of the second electrode layer on the base layer.

In some embodiments, the first electrode layer is of a continuous whole-layer structure.

In some embodiments, a material of the first electrode layer includes at least one of a transparent conductive material, metal, or alloy.

In some embodiments, the display panel includes a plurality of pixel units, and each pixel unit includes multiple sub-pixels having light-emitting colors that are not exactly the same. The plurality of first holes are arranged in multiple rows and multiple columns. Two adjacent first holes along a first direction are provided therebetween with at least one pixel unit, and two adjacent first holes along a second direction are provided therebetween with another at least one pixel unit. The first direction is a row direction in which the plurality of first holes are arranged, and the second direction is a column direction in which the plurality of first holes are arranged.

In some embodiments, an opening area of a first hole of the plurality of first holes is less than or equal to an area of a region where a pixel unit of the plurality of pixel units is located.

In some embodiments, the vibration film includes a polarizer and a protection layer arranged in a stack, and the polarizer is closer to the display panel as compared to the protection layer. The second electrode layer is disposed on a surface of the polarizer proximate to the display panel.

In some embodiments, the vibration film includes a polarizer and a protection layer arranged in a stack, and the polarizer is closer to the display panel as compared to the protection layer. The second electrode layer is disposed on a surface of the protection layer proximate to the display panel. The polarizer is provided with a plurality of second holes, and an orthographic projection of a second hole of the plurality of second holes on the base layer overlaps an orthographic projection of a first hole of the plurality of first holes on the base layer.

In some embodiments, the display module further includes a first signal line disposed on the base layer and connected to the first electrode layer, and a second signal line disposed on the vibration film and connected to the second electrode layer.

In some embodiments, the display panel further includes an encapsulation layer, and the encapsulation layer includes a first inorganic layer, an organic layer, and a second inorganic layer that are arranged in a stack. The first holes penetrate the encapsulation layer; and the encapsulation layer further includes a plurality of retaining wall structures, and a retaining wall structure of the plurality of retaining wall structures surrounds a first hole of the plurality of first holes.

In another aspect, a display device is provided. The display device includes a driving circuit and the display module described in any of the above embodiments. The driving circuit is configured to transmit signals to the first electrode layer and the second electrode layer.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of a display module, in accordance with some embodiments;

FIG. 3 is a structural diagram of a display panel, in accordance with some embodiments;

FIG. 4 is a structural diagram of another display panel, in accordance with some embodiments;

FIG. 5 is a structural diagram of a second electrode layer, in accordance with some embodiments;

FIG. 6 is a structural diagram of yet another display panel, in accordance with some embodiments;

FIG. 7 is a structural diagram of another second electrode layer, in accordance with some embodiments;

FIG. 8 is a structural diagram of still another display panel, in accordance with some embodiments;

FIG. 9 is a structural diagram of yet another second electrode layer, in accordance with some embodiments;

FIG. 10 is a diagram showing a distribution of first holes, in accordance with some embodiments;

FIG. 11 is a diagram showing another distribution of first holes, in accordance with some embodiments; and

FIG. 12 is a structural diagram of another display module, in accordance with some embodiments.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

Some embodiments may be described using the term “connected” and its derivatives. For example, the term “connected” may be used in the description of some embodiments to indicate that two or more components are in direct physical or electrical contact with each other.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals. It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

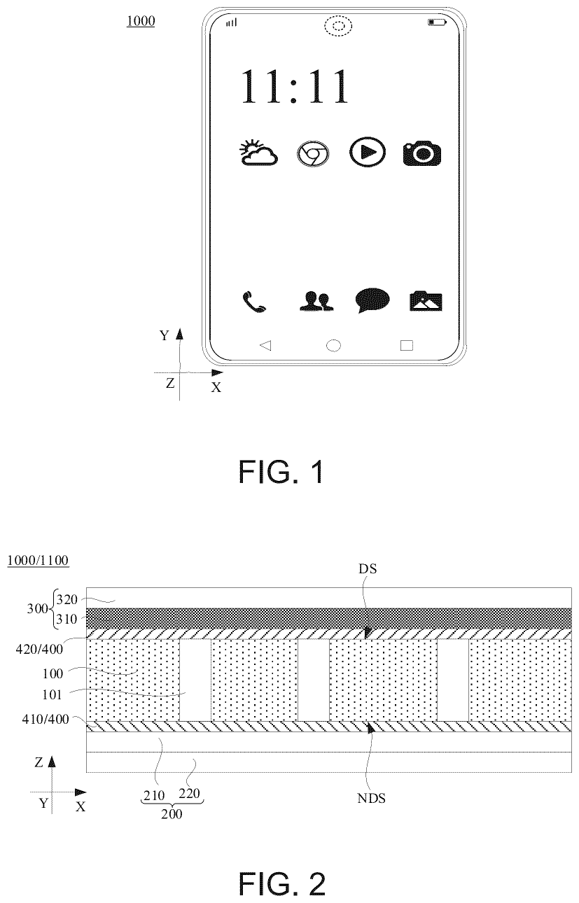

Some embodiments of the present disclosure provide a display device 1000, referring to FIG. 1, the display device 1000 may be any product or component having a display function, such as a television, a notebook computer, a tablet computer, a mobile phone, a personal digital assistant (PDA), a navigator, a wearable device, an augmented reality (AR) device, or a virtual reality (VR) device.

The above-mentioned display device 1000 may be an electroluminescent display device or a photoluminescent display device. In a case where the display device 1000 is an electroluminescent display device, the electroluminescent display device may be an organic light-emitting diode (OLED) display device or a quantum dot light-emitting diode (QLED) display device.

In some embodiments, the display device 1000 may be a display device 1000 that adopts screen sound-emitting technology. The screen sound-emitting technology refers to a technology in which a sound-emitting unit of the display device 1000 is designed to be integrated with a display module (display screen) and utilizes vibrations of the display module for emitting sound.

Common screen sound-emitting technologies include the following two solutions: one is the cantilever beam piezoelectric ceramic sound-conducting solution, and the other is a sound-emitting solution that uses a screen as a vibration source. Screen sound-emitting devices adopting the above two solutions emit sound spreading in all directions, that is, the sound lacks directionality and privacy.

Studies have found that the higher the frequency of sound, the stronger the directionality of the sound propagation. Based on this, the display device 1000 provided in the embodiments of the present disclosure adopts the high-frequency ultrasonic principle to enable the display device to emit ultrasonic waves (the sound wave frequency greater than 20,000 Hz), thereby making the ultrasonic waves have directionality. And the display device utilizes the self-demodulation effect of the ultrasonic waves in the air to generate audible sound (the sound wave frequency between 20 Hz and 20,000 Hz).

The related art provides a display device adopting screen sound-emitting technology, the display device includes a sound wave driving structure disposed on a non-display side of a display panel, in which the sound wave driving structure includes two electrode layers arranged opposite to each other, and a vibration space formed between the two electrode layers. The sound wave driving structure is used for driving the display panel and an optical film sheet on a display side of the display panel (such as a polarizer and a protection cover) to vibrate to emit sound. However, the vibration space in the sound wave driving structure is relatively large, resulting in a relatively large thickness of the display device, which is not conducive to making the display device thinner and lighter. Moreover, a vibration film (such as the polarizer and the protection cover) driven by the sound wave driving structure has a large mass (weight), resulting in high energy consumption, which is not conducive to reducing the power consumption of the display device.

In order to solve the above technical problems, the embodiments of the present disclosure provide a display device 1000. Referring to FIG. 2, the display device 1000 includes a display module 1100 and a driving circuit (not shown in the figure). The display module 1100 may include a display panel 100, a base layer 200, a vibration film 300, and a sound wave driving structure 400.

For example, in a case where the display device 1000 is an OLED display device, the display panel 100 may also be an OLED display panel. The OLED display panel may be, for example, a flexible display panel.

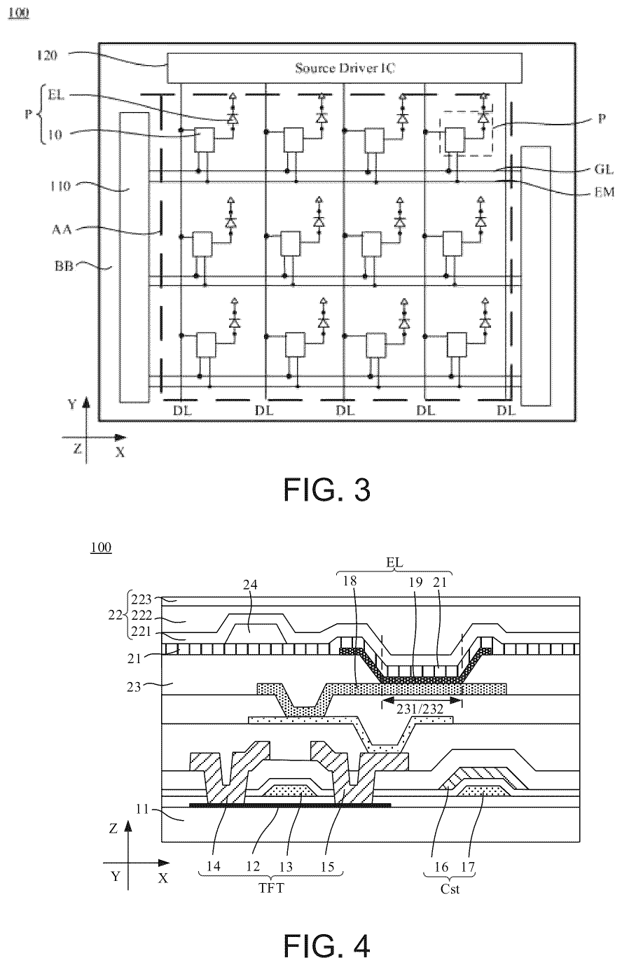

Referring to FIG. 3, the display panel 100 may include a display area AA and a peripheral area BB surrounding the display area AA. Of course, the peripheral area BB may also be located on only one side or on more than one side of the display area AA, and the embodiments of the present disclosure are not specifically limited thereto.

Continuing to refer to FIG. 3, the peripheral area BB may include a gate driving circuit 110 located on the left and right sides of the display area AA, and a source driving circuit 120 (e.g., a source driver integrated circuit, Source Driver IC for short) located on the upper side or lower side of the display area. The display area AA includes a plurality of sub-pixels P, and the plurality of sub-pixels P are arranged in multiple rows and multiple columns, where each row includes multiple sub-pixels P arranged along a first direction X (the horizontal direction in FIG. 3), and each column includes multiple sub-pixels P arranged along a second direction Y (a vertical direction in FIG. 3). Each sub-pixel P includes a pixel circuit 10 and a light-emitting device EL. For example, the first direction X and the second direction Y are perpendicular to each other.

In some embodiments, the plurality of sub-pixels P may include a plurality of sub-pixels of different light-emitting colors. For example, the plurality of sub-pixels P may include multiple first sub-pixels for emitting light of a first color, multiple second sub-pixels for emitting light of a second color, and multiple third sub-pixels for emitting light of a third color. For example, the first color, the second color and the third color may be three primary colors. For example, the first color is red, the second color is green, and the third color is blue.

In some other embodiments, the plurality of sub-pixels P may emit light of the same color. For example, the plurality of sub-pixels P may all emit white light. In this case, the display module 1100 may further include a color filter layer disposed on a display side of the display panel 100. For example, the color filter layer may include a black matrix layer and a plurality of filter portions, the black matrix layer includes a plurality of third openings, and at least a portion of each filter portion is located in one of the third openings. The plurality of filter portions may include multiple filter portions of a first color, multiple filter portions of a second color, and multiple filter portions of a third color, where the first color, the second color and the third color may be red, green and blue respectively.

In the embodiments of the present disclosure, description is given by taking an example where the plurality of sub-pixels P may include a plurality of sub-pixels of different light-emitting colors. The plurality of sub-pixels P may be divided into a plurality of pixel units P′. It will be appreciated that a sub-pixel P can be understood as the smallest light-emitting unit in the display panel 100, and a pixel unit P′ can be understood as the smallest unit in the display panel 100 that is capable of displaying all colors. The pixel unit P′ may include multiple sub-pixels, the multiple sub-pixels having light-emitting colors that are not exactly the same. For example, the pixel unit P′ may include one first sub-pixel for emitting red light, one second sub-pixel for emitting green light, and one third sub-pixel for emitting blue light. As another example, the pixel unit P′ may include one first sub-pixel, two second sub-pixels, and one third sub-pixel. The pixel unit P′ may also have other combinations of different sub-pixels P, which will not be enumerated in the embodiments of the present disclosure.

Each sub-pixel P includes a pixel circuit 10 and a light-emitting device EL. As shown in FIG. 4, the pixel circuit 10 includes multiple switching devices and at least one capacitor Cst. The switching device may, for example, include a field effect transistor (such as a thin film transistor, TFT for short), or another switching device with the same properties, which is not specifically limited in the embodiments of the present disclosure. For example, in the embodiments of the present disclosure, description is given by taking an example where the switching device is a TFT.

For example, the pixel circuit 10 may include multiple TFTs and at least one capacitor Cst. For example, the pixel circuit may be a “3T1C circuit”, a “7T1C circuit”, an “8T1C circuit”, or any other pixel circuit, which is not specifically limited in the embodiments of the present disclosure. Here, “T” represents a TFT, the number before “T” represents the number of the TFTs; and “C” represents a capacitor, and the number before “C” represents the number of the capacitors Cst.

The display panel 100 further includes a plurality of gate lines GL and a plurality of data lines DL. Pixel circuits 10 of each row of sub-pixels P are electrically connected to the gate driving circuit 110 through at least one gate line GL, and pixel circuits 10 of each column of sub-pixels P are electrically connected to the source driving circuit 120 through at least one data line DL.

Referring to FIGS. 3 and 4, the display panel 100 includes a substrate 11; the TFT may include a semiconductor layer 12, a gate 13, a source 14, and a drain 15 that are located on the substrate 11; the capacitor Cst may include a first electrode plate 16 and a second electrode plate 17; and the light-emitting device EL includes an anode 18, a light-emitting functional layer 19 and a cathode layer 21. It can be understood that the display panel 100 further includes at least one insulating layer located between two adjacent conductive layers, and an encapsulation layer 22 located on a side of the cathode layer 21 away from the substrate 11.

In some embodiments, the encapsulation layer 22 may include a first inorganic material layer (i.e., a first inorganic layer) 221, an organic material layer (i.e., an organic layer) 222, and a second inorganic material layer (i.e., a second inorganic layer) 223 that are stacked in a direction away from the substrate 11. Here, the first inorganic material layer 221 and the second inorganic material layer 223 are used for insulating water vapor and oxygen in the air, reducing the risk of water vapor and oxygen intrusion into the interior of the display panel 100 (e.g., the interior of the light-emitting functional layer 19); and the organic material layer 222 is capable of flattening a light-emitting surface of the display panel 100 and releasing stress in the display panel 100.

In some embodiments, the display panel 100 may further include other film layers or structures. For example, the display panel 100 may further include a pixel defining layer 23 located between the anode 18 and the light-emitting functional layer 19, a spacer layer 24 disposed between the pixel defining layer 23 and the cathode layer 21, a touch structure and a color filter layer that are disposed on a side of the encapsulation layer 22 away from the substrate 11, etc., which are not specifically limited in the embodiments of the present disclosure.

Here, the pixel defining layer 23 includes a plurality of second openings 231, and each second opening 231 exposes at least a portion of a region of an anode 18; and at least a portion of the light-emitting functional layer 19 is located in a second opening 231. Moreover, a second opening 231 of the pixel defining layer 23 defines a light-emitting region 232 of a sub-pixel P. That is, a region of the second opening 231 is the same as a region of the light-emitting region 232. The spacer layer 24 may be used for supporting a mask in an evaporation process.

The display panel 100 has a display side (the upper side of the display panel 100 in FIG. 4) and a non-display side (the lower side of the display panel 100 in FIG. 4), where the display side refers to a side of the display panel 100 for displaying images, and the non-display side refers to a side of the display panel 100 away from the display side. That is, the display side and the non-display side are opposite sides of the display panel 100, respectively.

Referring to FIG. 2, the display panel 100 includes a plurality of first holes 101. The first hole 101 penetrates the display panel 100 and is configured to provide a vibration space for a second electrode layer 420 of the sound wave driving structure 400 to reduce the thickness of the display module 1100 (see below). For example, the first hole 101 may penetrate the display panel 100 along a third direction Z. The third direction Z may be perpendicular to the first direction X and the second direction Y. That is, the third direction Z is a direction perpendicular to a plane where the substrate 11 is located.

Referring to FIG. 2, the base layer 200 is disposed on the non-display side NDS of the display panel 100 and is configured to support and protect the display panel 100. In some embodiments, the base layer 200 may include a buffer layer 210 and a support layer 220 arranged in a stack, where the support layer 220 is farther away from the display panel 100 as compared to the buffer layer 210.

For example, the buffer layer 210 is configured to provide buffering for the display panel 100 to reduce stress on the display panel 100 due to shaking or collision, so as to reduce the risk of damage to the display panel 100. For example, a material of the buffer layer 210 may include one or more of foam (Foam), polyimide (PI), polyethylene terephthalate (PET), thermoplastic polyurethane (TPU), cycloolefin polymer (COP) and triacetate (TAC).

For example, the support layer 220 is configured to provide rigid support for the display panel 100, so that the display panel 100 and the display device 1000 have a certain rigidity and can maintain a certain shape, thereby preventing the display panel 100 and the display device 1000 from unexpected deformation. For example, a material of the support layer 220 may be metal. For example, the material of the support layer 220 may be stainless steel, titanium alloy, or the like, which will not be enumerated in the embodiments of the present disclosure. As another example, the material of the support layer 220 may also be non-metal, such as plastic, glass fiber composite material or carbon fiber composite material, which will not be enumerated in the embodiments of the present disclosure.

In some embodiments, the base layer 200 may further include other film layer structures. For example, the base layer 200 may further include an adhesive layer located between the buffer layer 210 and the support layer 220. The embodiments of the present disclosure do not specifically limit the structure of the base layer 200. For example, the base layer 200 may be a collection of all structures on the non-display side of the display panel 100.

Referring to FIG. 2, the vibration film 300 is disposed on the display side DS of the display panel 100, and the vibration film 300 is a sound source for the display device 1000 to generate sound waves. That is, the sound wave driving structure 400 is used for driving the vibration film 300 to vibrate to generate sound waves.

In some embodiments, the vibration film 300 may include a polarizer 310 and a protection layer 320. The polarizer 310 can reduce the reflection of natural light from the display side of the display panel 100, so as to enhance the display effect of the display device 1000. The protection layer 320 is configured to protect the display panel 100. For example, the protection layer 320 may be a glass cover.

The sound wave driving structure 400 includes a first electrode layer 410 and a second electrode layer 420. The first electrode layer 410 is disposed on a surface of the base layer 200 proximate to the display panel 100, and the second electrode layer 420 is disposed on the vibration film 300.

An orthographic projection of the first electrode layer 410 and an orthographic projection of the second electrode layer 420 on the base layer 200 each cover at least orthographic projections of the plurality of first holes 101 on the base layer 200. That is to say, the first electrode layer 410 and the second electrode layer 420 are at least partially located at opposite ends of the first holes 101 along the third direction Z. The plurality of first holes 101 can provide a vibration space for the first electrode layer 410 and/or the second electrode layer 420. That is to say, the first electrode layer 410 and/or the second electrode layer 420 may vibrate at opposite sides of the first holes 101. In the embodiments of the present application, the vibration space of the sound wave driving structure 400 is integrated into the plurality of first holes 101 of the display panel 100. Therefore, there is no need to set up an additional vibration space, which is conducive to reducing the thickness of the display module 1100 and achieving the thinness and light weight of the display device 1000.

Since the vibration film 300 is disposed on the display side of the display panel 100, that is, the vibration film 300 does not include the display panel 100. Moreover, the second electrode layer 420 is disposed on the vibration film 300. Based on this, when the second electrode layer 420 drives (actuates) the vibration film 300 to vibrate, there is no need to synchronously drive the display panel 100 to vibrate. In this way, the overall mass (weight) of the vibration film 300 may be reduced, thereby reducing the energy required for the vibration of the second electrode layer 420, reducing the energy consumption of the sound wave driving structure 400, and achieving the purpose of reducing the power consumption of the display device 1000.

In some embodiments, electrical signals with the same electrical property may be applied to the first electrode layer 410 and the second electrode layer 420 to make the first electrode layer 410 and the second electrode layer 420 repel each other, and electrical signals with opposite electrical properties may be applied to the first electrode layer 410 and the second electrode layer 420 to make the first electrode layer 410 and the second electrode layer 420 attract each other. During the process of mutual attraction and repulsion between the first electrode layer 410 and the second electrode layer 420, the second electrode layer 420 vibrates at a side of the first holes 101, thereby driving the vibration film 300 to vibrate and generate sound.

It can be understood that the same electrical property of electrical signals means that the types of charges of the electrical signals are the same, which are all positive charges or all negative charges. For example, positive charges or negative charges are input to both the first electrode layer 410 and the second electrode layer 420, so that the first electrode layer 410 and the second electrode layer 420 repel each other; and the opposite electrical properties of electrical signals mean that types of charges are opposite, one is a positive charge and the other is a negative charge. For example, positive charges are input to the first electrode layer 410 while negative charges are input to the second electrode layer 420; or negative charges are input to the first electrode layer 410 while positive charges are input to the second electrode layer 420, so that the first electrode layer 410 and the second electrode layer 420 attract each other.

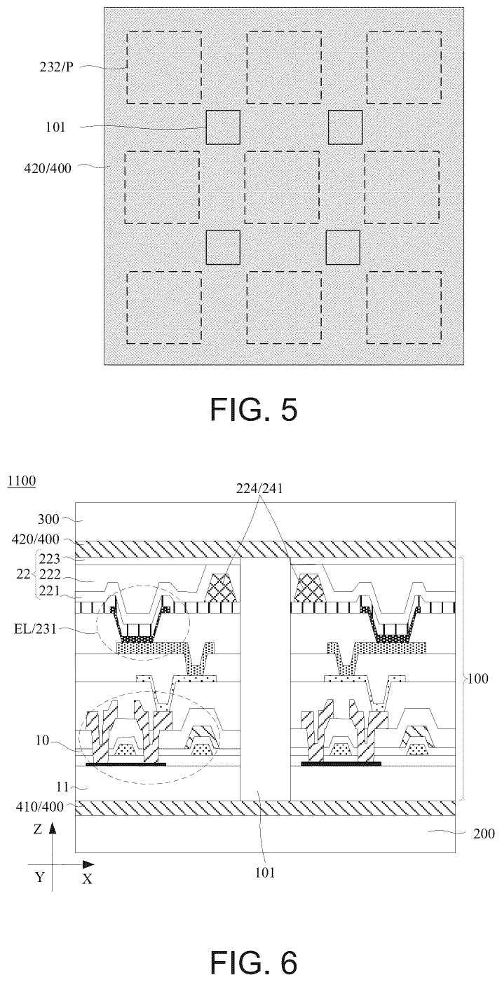

In some embodiments, referring to FIGS. 5 and 6, the second electrode layer 420 is of a continuous whole-layer structure, and a material of the second electrode layer 420 includes a transparent conductive material. The second electrode layer 420 is of the continuous whole-layer structure, which may reduce the difficulty of manufacturing the second electrode layer 420 and simplify the processing procedures of the second electrode layer 420 (there is no need to perform patterning on the second electrode layer 420). The orthographic projection of the second electrode layer 420 on the base layer 200 overlaps orthographic projections of light-emitting regions 232 of the plurality of sub-pixels P on the base layer 200. The material of the second electrode layer 420 includes the transparent conductive material, which may reduce the influence of the second electrode layer 420 on the light extraction rate of the display panel 100.

It can be understood that the transparent conductive material refers to a material having a light transmittance greater than a certain threshold and is capable of conducting electricity. For example, the transparent conductive material may be a conductive material having a light transmittance greater than 75%, 85%, 90%, 97% or other values, which is not specifically limited by the embodiments of the present disclosure.

For example, the material of the second electrode layer 420 may include indium tin oxide (ITO) or indium zinc oxide (IZO).

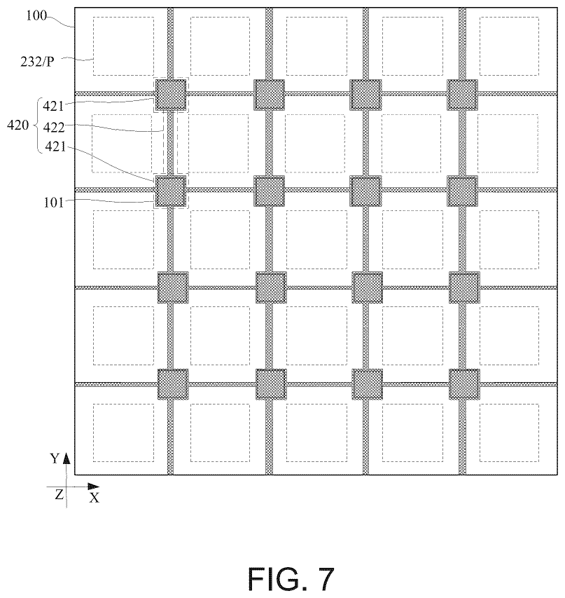

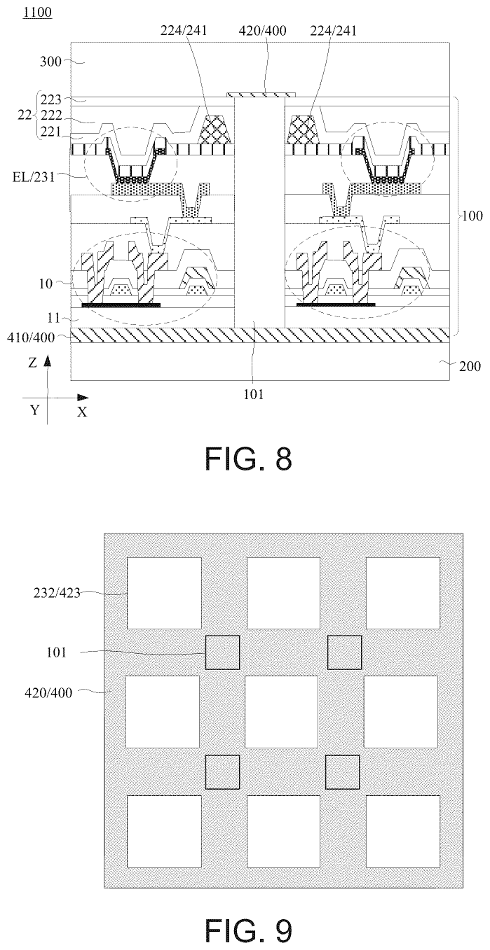

In some other embodiments, as shown in FIGS. 7 and 8, the orthographic projection of the second electrode layer 420 on the base layer 200 is non-overlapping with orthographic projections of light-emitting regions 232 of the plurality of sub-pixels P on the base layer 200. That is, the second electrode layer 420 is not of a continuous whole-layer structure. The second electrode layer 420 does not cover the light-emitting regions 232 of the sub-pixels P, so light emitted by the sub-pixels P can be directly emitted from the display side of the display device 1000 without passing through the second electrode layer 420. In this way, the influence of the second electrode layer 420 on the light-emitting efficiency of the display device 1000 may be further reduced.

In some embodiments, as shown in FIG. 8, the orthographic projection of the second electrode layer 420 on the base layer 200 is non-overlapping with orthographic projections of a plurality of pixel circuits 10 of the plurality of sub-pixels P on the base layer 200. In this way, the risk of parasitic capacitance generated between the second electrode layer 420 and the pixel circuits 10 may be reduced, reducing the influence of the second electrode layer 420 on the pixel circuits 10.

In some embodiments, referring to FIG. 7, the second electrode layer 420 includes a plurality of conductive blocks 421 and a plurality of connection lines 422, and an orthographic projection of each conductive block 421 on the base layer 200 overlaps an orthographic projection of a first hole 101 on the base layer 200. For example, the orthographic projection of each conductive block 421 on the base layer 200 may completely overlap or partially overlap an orthographic projection of a first hole 101 on the base layer 200.

In some embodiments, the orthographic projection of the conductive block 421 on the base layer 200 completely overlaps the orthographic projection of the first hole 101 on the base layer 200. That is, in a top view towards the base layer 200, each conductive block 421 is located in a first hole 101, and a boundary of the conductive block 421 substantially coincides with a boundary of the first hole 101. In this way, not only may the area of the conductive block 421 be reduced, thereby reducing the material cost of the second electrode layer 420, but also the conductive block 421 may be ensured to have a sufficient size for vibration, thereby improving the reliability of the sound wave driving structure 400.

Of course, in some other embodiments, the orthographic projection of the conductive block 421 on the base layer 200 may also partially overlap the orthographic projection of the first hole 101 on the base layer 200.

For example, the orthographic projection of the conductive block 421 on the base layer 200 partially overlapping the orthographic projection of the first hole 101 on the base layer 200 may mean that in a top view towards the base layer 200, each conductive block 421 is located in a first hole 101, and at least a portion of a boundary of the conductive block 421 has a spacing from a boundary of the first hole 101. In this way, the area of the conductive block 421 may be reduced, so as to reduce the influence of the conductive block 421 on the light output efficiency of the display panel 100, and the overall area of the second electrode layer 420 may be reduced, so as to reduce the material cost of the second electrode layer 420.

Alternatively, the orthographic projection of the conductive block 421 on the base layer 200 partially overlapping the orthographic projection of the first hole 101 on the base layer 200 may also mean that in a top view towards the base layer 200, a first hole 101 is located in a conductive block 421, and at least a portion of a boundary of the first hole 101 has a spacing from a boundary of the conductive block 421. In this way, it is conducive to reducing the alignment precision of the second electrode layer 420 with the display panel 100, so that at least a portion of each conductive block 421 faces a first hole 101, ensuring that each conductive block 421 is able to vibrate at a side of the first hole 101, and enhancing the reliability of the sound wave driving structure 400.

In some other embodiments, the second electrode layer 420 may also be of a grid structure having a plurality of first openings 423. In a top view towards the base layer 200, light-emitting regions 232 of the plurality of sub-pixels P are located in the plurality of first openings 423. The above grid structure (e.g., a metal grid structure) can also reduce the shielding of the light-emitting regions 232 of the sub-pixels P by the second electrode layer 420, thereby reducing the influence of the second electrode layer 420 on the light output efficiency of the display panel 100.

For example, as shown in FIG. 9, in a case where the second electrode layer 420 is of a grid structure, a region of each first opening 423 may substantially coincide with a light-emitting region 232 of a sub-pixel P. That is, in a top view towards the base layer 200, the second electrode layer 420 is non-overlapping with the light-emitting regions 232 of the plurality of sub-pixels P, and boundaries of the plurality of first openings 423 substantially coincide with boundaries of the light-emitting regions 232 of the plurality of sub-pixels P, respectively.

In some embodiments, in a case where the orthographic projection of the second electrode layer 420 on the base layer 200 does not cover the orthographic projections of the light-emitting regions 232 of the sub-pixels P on the base layer 200, that is, in a case where the orthographic projection of the second electrode layer 420 on the base layer 200 is non-overlapping with the orthographic projections of the light-emitting regions 232 of the sub-pixels P on the base layer 200, or the second electrode layer 420 includes the plurality of conductive blocks 421 and the plurality of connection lines, or the second electrode layer is of the grid structure, the material of the second electrode layer 420 may include a transparent conductive material, and/or metal or alloy. For example, the transparent conductive material may include at least one of ITO and IZO; the metal material may include at least one of silver (Argentum, Ag for short), aluminum (Al), and copper (Cu); and the alloy material may include magnesium-silver alloy, aluminum-lithium alloy, or the like, which will not be enumerated in the embodiments of the present disclosure.

In some embodiments, the orthographic projection of the first electrode layer 410 on the base layer 200 substantially overlaps the orthographic projection of the second electrode layer 420 on the base layer 200. That is, the shape of the first electrode layer 410 may be substantially the same as that of the second electrode layer 420. In this way, when patterning the second electrode layer 420 (the second electrode layer 420 is not of a continuous whole-layer structure), the first electrode layer 410 and the second electrode layer 420 can use the same mask, and there is no need to add an additional mask for the first electrode layer 410. In other words, the first electrode layer 410 is practicable in process and moreover, the material cost of the first electrode layer 410 may also be reduced.

Of course, in some other embodiments, the first electrode layer 410 may also be of a continuous whole-layer structure. In this way, the difficulty of manufacturing the first electrode layer 410 may be reduced, which is conducive to improving the processing efficiency of the sound wave driving structure 400 and improving the manufacturing efficiency of the display device 1000.

Since the first electrode layer 410 is disposed on the non-display side of the display panel 100, that is, the first electrode layer 410 will not cause a negative impact on the light output efficiency of the display panel 100 and the display device 1000, based on this, the material of the first electrode layer 410 may include at least one of a transparent conductive material, metal and alloy. The transparent conductive material may include ITO and/or IZO; the metal material may include at least one of silver, aluminum and copper; and the alloy material may include magnesium-silver alloy, aluminum-lithium alloy, or the like, which will not be enumerated in the embodiments of the present disclosure.

For example, the material of the first electrode layer 410 may be the same as that of the second electrode layer 420, which is conducive to enhancing the homogeneity of materials of the sound wave driving structure 400, and reducing the manufacturing cost of the first electrode layer 410 and the second electrode layer 420.

For example, in a case where the first electrode layer 410 is of a single-layer film structure, the material of the first electrode layer 410 may include one of a transparent conductive material, metal, and alloy; and in a case where the first electrode layer 410 is of a multi-layer film structure, for the multi-layer film structure included in the first electrode layer 410, each layer of the film structure may use one of a transparent conductive material, metal, and alloy, and different layers of the film structure may use the same or different materials.

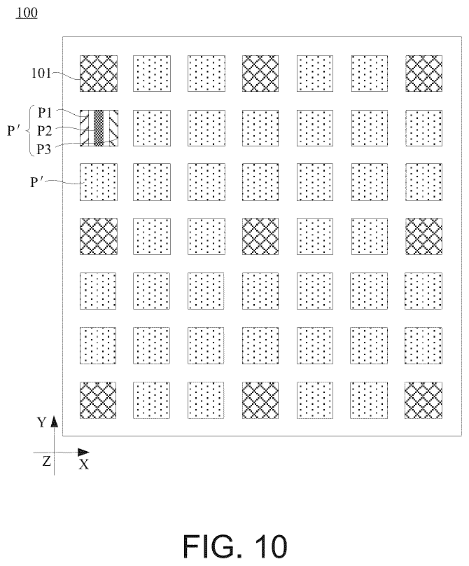

In some embodiments, referring to FIG. 10, the plurality of first holes 101 are arranged in multiple rows and multiple columns, where each row includes multiple first holes 101 arranged along a first direction X, and each column includes multiple first holes 101 arranged along a second direction Y. At least one pixel unit P′ is provided between two adjacent first holes along the first direction, and another at least one pixel unit P′ is provided between two adjacent first holes along the second direction. That is to say, the first holes 101 may be disposed at intervals between the plurality of pixel units P′. The first direction X is a row direction of the plurality of first holes 101 (substantially parallel to a row direction of the plurality of sub-pixels P), and the second direction Y is a column direction of the plurality of first holes 101 (substantially parallel to a column direction of the plurality of sub-pixels P). In this way, it is conducive to enhancing the distribution uniformity of the first holes 101, so that the second electrode layer 420 can drive the vibration film 300 to vibrate uniformly at various positions, and thus enhance the sound emitting effect of the vibration film 300.

In some embodiments, the opening area of a first hole 101 is less than or equal to the area of a region where a pixel unit P′ is located. The opening area of the first hole 101 is not too large (not greater than the area of a pixel unit P′), which may reduce the risk of dark spots appearing on the display panel 100, thereby conducive to ensuring the display quality of the display device 1000.

For example, in some display products with relatively low pixel density requirements, the opening area of a first hole 101 may be equal to the area of a pixel unit P′. In this way, it is conducive to increasing the area of the first hole 101, increasing the area of a portion of the second electrode layer 420 that is capable of generating vibrations, and thus enhancing the sound-emitting effect of the sound wave driving structure 400.

For example, in some display products with relatively low pixel density requirements, the opening area of a first hole 101 may be less than the area of a pixel unit P′. In this way, it is conducive to reducing the ratio of the area of the first hole 101 to that of the display panel, so the display panel 100 can have more space for arranging sub-pixels P, thereby conducive to enhancing the pixel density of the display panel 100. For example, the opening area of the first hole 101 may be substantially equal to the area of a region where one or two sub-pixels P are located, or the opening area of the first hole 101 may be less than that of a region where one sub-pixel P is located, which are not limited in the embodiments of the present disclosure.

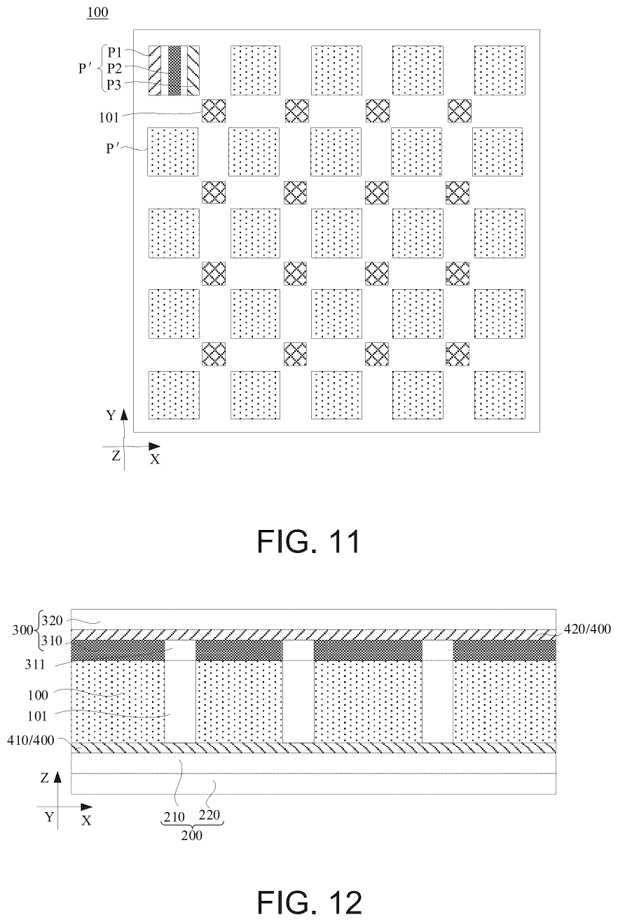

In some other embodiments, as shown in FIG. 11, the plurality of first holes 101 are arranged in multiple rows and multiple columns, and each first hole 101 is located between four pixel units P′ in two adjacent rows and two columns. In this way, the influence of the first holes 101 on the arrangement of the plurality of sub-pixels P may be reduced, which is conducive to improving the pixel density of the display panel 100.

In some embodiments, as shown in FIG. 2, the vibration film 300 may include a polarizer 310 and a protection layer 320. The second electrode layer 420 is disposed on a surface of the polarizer 310 proximate to the display panel 100. That is to say, the second electrode layer 420 can be directly manufactured on the polarizer 310 using the polarizer 310 as a substrate layer. Alternatively, the second electrode layer 420 may be first formed on a substrate layer, and then the second electrode layer 420 and the polarizer 310 may be bonded together by an adhesive layer. Embodiments of the present disclosure are not specifically limited in the above regard.

It can be understandable that since the display panel 100 is provided with the first holes 101, it is not possible to use the display panel 100 as the substrate layer and directly manufacture the second electrode layer 420 on the encapsulation layer of the display panel 100. Arranging the second electrode layer 420 on the polarizer 310 may improve the structural stability of the sound wave driving structure 400.

In some other embodiments, referring to FIG. 12, the second electrode layer 420 may also be disposed between the polarizer 310 and the protection layer 320, and disposed on a surface of the protection layer 320 proximate to the polarizer 310. The polarizer 310 is provided with a plurality of second holes 311, and an orthographic projection of a second hole 311 on the base layer 200 overlaps an orthographic projection of a first hole 101 on the base layer 200. In this way, the orthographic projection of the second electrode layer 420 on the base layer 200 can also cover orthographic projections of the second holes 311 on the base layer 200, and the second electrode layer 420 can vibrate at a side of a space formed by the second hole 311 and the first hole 101, which is conducive to increase the interval between the first electrode layer 410 and the second electrode layer 420, increase the volume of the vibration space along the third direction Z, and reduce the risk of short circuit between the first electrode layer 410 and the second electrode layer 420.

In some embodiments, the base layer 200 is provided thereon with a first signal line (not shown in the figure) connected to the first electrode layer 410, and the vibration film 300 is provided thereon with a second signal line (not shown in the figure) connected to the second electrode layer 420. The first signal line is configured to transmit an electrical signal to the first electrode layer 410, and the second signal line is configured to transmit another electrical signal to the second electrode layer 420. For example, the first signal line and the second signal line are electrically connected to the driving circuit, respectively, and the driving circuit transmits the signals to the first electrode layer 410 and the second electrode layer 420 through the first signal line and the second signal line.

In some embodiments, as shown in FIGS. 6 and 8, the first holes 101 of the display panel 100 penetrate the encapsulation layer 22, and the encapsulation layer 22 further includes a plurality of retaining wall structures 224. A retaining wall structure 224 surrounds a first hole 101 and is configured to separate the organic material layer 222 in the encapsulation layer 22 from the first hole 101, thereby reducing the risk of a material for forming the organic material layer 222 flowing into the first hole 101, improving the encapsulation performance of the encapsulation layer 22, and reducing the risk of water and oxygen invading the display panel 100 from a side wall of the first hole 101 along the organic material layer 222.

For example, the retaining wall structure 224 may be made of the same material and be disposed in the same layer as the spacer layer 24. The retaining wall structure 224 may include one or more pads 241, each pad 241 surrounding a first hole 101; and in a case where the retaining wall structure 224 includes multiple pads 241, the multiple pads 241 are arranged at radial intervals along the first hole 101. Here, FIGS. 6 and 8 both exemplarily show a single pad 241.

In some embodiments, it is further possible to fill a cavity formed by a first hole 101 with an inert gas (e.g., nitrogen, helium, etc.) to reduce the risk that oxygen enters into the display panel 100 via the first hole 101 and causes the organic material within the display panel 100 to be oxidized, and thus to reduce the influence of the first hole 101 on the sealing of the display panel 100.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel having a display side and a non-display side, wherein the display panel includes a plurality of first holes, and the first holes penetrate the display panel;
a base layer disposed on the non-display side of the display panel;
a vibration film disposed on the display side of the display panel; and
a sound wave driving structure including a first electrode layer and a second electrode layer, wherein the first electrode layer is disposed on a surface of the base layer proximate to the display panel, and the second electrode layer is disposed on the vibration film; and an orthographic projection of the first electrode layer and an orthographic projection of the second electrode layer on the base layer cover at least orthographic projections of the plurality of first holes on the base layer.

2. The display module according to claim 1, wherein a material of the second electrode layer includes a transparent conductive material, and the second electrode layer is of a continuous whole-layer structure.

3. The display module according to claim 1, wherein
the display panel includes a plurality of sub-pixels, and each sub-pixel includes a light-emitting region; and
the orthographic projection of the second electrode layer on the base layer is non-overlapping with an orthographic projection of the light-emitting region on the base layer.

4. The display module according to claim 3, wherein
the sub-pixel includes a pixel circuit and a light-emitting device; and
the orthographic projection of the second electrode layer on the base layer is non-overlapping with an orthographic projection of the pixel circuit on the base layer.

5. The display module according to claim 3, wherein the second electrode layer includes:
a plurality of conductive blocks, an orthographic projection of each conductive block on the base layer overlapping an orthographic projection of a first hole of the plurality of first holes on the base layer; and
a plurality of connection lines, configured to electrically connect the plurality of conductive blocks.

6. The display module according to claim 5, wherein in a top view towards the base layer, each conductive block is located in a first hole of the plurality of first holes, and a boundary of the conductive block coincides with a boundary of the first hole.

7. The display module according to claim 3, wherein the second electrode layer is of a grid structure having a plurality of first openings; and in a top view towards the base layer, light-emitting regions of the plurality of sub-pixels are located in the plurality of first openings.

8. The display module according to claim 3, wherein a material of the second electrode layer includes a transparent conductive material, and/or the material of the second electrode layer includes metal or alloy.

9. The display module according to claim 1, wherein the orthographic projection of the first electrode layer on the base layer overlaps the orthographic projection of the second electrode layer on the base layer.

10. The display module according to claim 1, wherein the first electrode layer is of a continuous whole-layer structure.

11. The display module according to claim 1, wherein a material of the first electrode layer includes at least one of a transparent conductive material, metal, or alloy.

12. The display module according to claim 1, wherein the display panel includes a plurality of pixel units, and each pixel unit includes multiple sub-pixels having light-emitting colors that are not exactly the same; and
the plurality of first holes are arranged in multiple rows and multiple columns; two adjacent first holes along a first direction are provided therebetween with at least one pixel unit, and two adjacent first holes along a second direction are provided therebetween with another at least one pixel unit; and the first direction is a row direction in which the plurality of first holes are arranged, and the second direction is a column direction in which the plurality of first holes are arranged.

13. The display module according to claim 12, wherein an opening area of a first hole of the plurality of first holes is less than or equal to an area of a region where a pixel unit of the plurality of pixel units is located.

14. The display module according to claim 1, wherein the vibration film includes a polarizer and a protection layer arranged in a stack, and the polarizer is closer to the display panel as compared to the protection layer; and
the second electrode layer is disposed on a surface of the polarizer proximate to the display panel.

15. The display module according to claim 1, wherein the vibration film includes a polarizer and a protection layer arranged in a stack, and the polarizer is closer to the display panel as compared to the protection layer; and
the second electrode layer is disposed on a surface of the protection layer proximate to the display panel;
wherein the polarizer is provided with a plurality of second holes, and an orthographic projection of a second hole of the plurality of second holes on the base layer overlaps an orthographic projection of a first hole of the plurality of first holes on the base layer.

16. The display module according to claim 1, further comprising:
a first signal line disposed on the base layer and connected to the first electrode layer; and
a second signal line disposed on the vibration film and connected to the second electrode layer.

17. The display module according to claim 1, wherein
the display panel further includes an encapsulation layer, and the encapsulation layer includes a first inorganic layer, an organic layer, and a second inorganic layer that are arranged in a stack; and
the first holes penetrate the encapsulation layer; and the encapsulation layer further includes a plurality of retaining wall structures, and a retaining wall structure of the plurality of retaining wall structures surrounds a first hole of the plurality of first holes.

18. A display device, comprising:
the display module according to claim 1; and
a driving circuit, configured to transmit signals to the first electrode layer and the second electrode layer.

19. The display module according to claim 2, wherein the material of the second electrode layer includes indium tin oxide and/or indium zinc oxide.

20. The display module according to claim 5, wherein in a top view towards the base layer,
each conductive block is located in a first hole of the plurality of first holes, and at least a portion of a boundary of the conductive block has a spacing from a boundary of the first hole; or a first hole of the plurality of first holes is located in a conductive block of the plurality of conductive blocks, and at least a portion of a boundary of the conductive block has a spacing from a boundary of the first hole.
